(19) United States
(12) Patent Application Publication
(10) Pub. No.: US 2026/0111636 A1
(43) Pub. Date: Apr. 23, 2026

(54) GRAPH-BASED VISUALIZATION OF WAYPOINT FOR DETECTING DESIGN ERROR IN INTEGRATED CIRCUIT DESIGN

(71) Applicant: Synopsys, Inc., Sunnyvale, CA (US)

(72) Inventors: Subhadip Halder, Karnataka (IN); Prasun Das, Cupertino, CA (US); Himanshu Jain, Portland, OR (US); Pallab Dasgupta, Santa Clara, CA (US); Per Bjesse, Portland, OR (US)

(21) Appl. No.: 18/920,470

(22) Filed: Oct. 18, 2024

(51) Int. Cl. G06F 30/33; G06F 30/327

(52) U.S. Cl. CPC G06F 30/33; G06F 30/327

(57) ABSTRACT

A non-transitory computer readable medium includes stored instructions, which when executed by a processor, cause the processor to acquire a plurality of graphs that model results of a plurality of bug hunting searches for a register transfer level design, wherein the plurality of bug hunting searches determines a design error in the register transfer level design, construct a composite graph using the plurality of graphs, wherein the composite graph models a plurality of causal relationships between a plurality of detected bugs and a plurality of helper properties covered by the plurality of bug hunting searches, and execute an additional bug hunting search whose parameters are configured based on the composite graph.

### TECHNICAL FIELD

The present disclosure relates generally to verification of integrated circuit design and relates more particularly to graph-based visualization of waypoints for detecting design errors in integrated circuit designs.

### BACKGROUND

In the field of integrated circuit design, formal verification refers to a family of methods that read a register transfer level (RTL) circuit design and prove or disprove the design against a formal specification. Formal verification engines can be classified into two broad categories: proof engines, which try to formally prove an assertion or formal property, and bug hunting engines, which try to find a failed assertion (also referred to as a design error or bug) using formal methods such as bounded model checking (BMC).

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates a flow diagram of one example of a method for visualizing waypoints for detecting design errors in integrated circuit designs.

FIG. 2 illustrates a fragment of an example graph that may be constructed from a bug hunting search by a semi-formal bug hunting engine and acquired in FIG. 1.

FIG. 3 illustrates a first example graph fragment and a second example graph fragment that may be merged to construct a composite graph.

FIG. 4 illustrates an example scoreboard that may be generated using the data in the example composite graph in FIG. 3.

FIG. 5 illustrates a graphic showing how insights derived from a scoreboard such as the scoreboard in FIG. 4 may be used to tune the parameters of new bug hunting searches to detect additional bugs in a bug-prone zone of a register transfer level design space.

FIG. 6 depicts a flowchart of various processes used during the design and manufacture of an integrated circuit in accordance with some embodiments of the present disclosure.

FIG. 7 depicts a diagram of an example emulation system in accordance with some embodiments of the present disclosure.

FIG. 8 depicts a diagram of an example computer system in which embodiments of the present disclosure may operate.

### DETAILED DESCRIPTION

Aspects of the present disclosure relate to graph-based visualization of waypoints for detecting design errors in integrated circuit designs. As discussed above, formal verification refers to a family of methods that read an RTL circuit design and prove or disprove the design against a formal specification. Formal verification engines can be classified into two broad categories: proof engines, which try to formally prove an assertion or formal property, and bug hunting engines, which try to find an assertion failure (also referred to as a design error or bug) using formal methods such as bounded model checking.

Fully formal bug hunting engines suffer from scalability limitations. That is, as these formal bug hunting engines expand deeper into the design state space, the time and space complexity of the search grows exponentially, which limits the ability of the formal bug hunting engines to search for deep corner-case bugs in the RTL design. As such, semi-formal bug hunting engines, which typically do not suffer from such scalability limitations, are becoming more sought after in the formal verification domain. Semi-formal bug hunting engines may use simulation techniques to reach deep states in the design state space and may deploy formal bug hunting techniques (such as BMC) to exhaustively search these deep states for bugs that would otherwise be difficult to detect.

However, even semi-formal bug hunting engines may take many cycles to detect more complex bugs. For instance, it is not uncommon to find bugs that are sensitized when a memory or a first in first out (FIFO) buffer is full. In such cases, semi-formal bug hunting engines may be aided by helper properties that define scenarios which are highly likely to lead to bugs. A helper property in this context is a formal property that is true in some specific states of the RTL design (i.e., states that can potentially sensitize certain types of design errors if those design errors are present). A state that satisfies a helper property may also be referred to as a helper state. When a helper state is reached, the helper property may be said to be covered. Therefore, helper properties may be considered special types of covered properties that are either explicitly written by a user or internally generated by a formal verification tool. Helper states are potential waypoints to deep corner-case bugs in the RTL design.

Covering a helper property may require the help of other covered properties. For instance, in the case of a complex RTL design containing a large FIFO, it may be difficult to reach the FIFO full state using fully formal bug-hunting engines. However, if a set of covered properties that capture intermediate states of the FIFO is added, it may become possible for a semi-formal bug hunting engine to use these intermediate states as waypoints which can be followed to drive the RTL design into the FIFO full state. Then, formal bug hunting techniques may be deployed to search for corner-case bugs that are only sensitized when the FIFO overflows.

Formal bug hunting engines provide a counter example trace for each failed assertion and a witness trace for each covered property. A semi-formal bug hunting engine may deploy a formal bug hunting exploration from helper states that cover a helper property. This exploration may find failed assertions in the vicinity of the helper states, or may reach states that cover other helper properties. The states that cover other helper properties may become starting states of new semi-formal bug hunting searches. Thus, helper properties may guide the bug hunting process to search different areas of the RTL design in the hope of finding difficult to detect corner-case bugs.

A bug typically affects multiple valid behaviors of an RTL design. Thus, when a bug in the RTL design causes a property to fail in one part of the formal state space, it is highly likely that the bad behavior sensitizes other failed assertions in nearby states. Failed states that are co-located in this manner may be referred to as bug nests. A bug nest represents a set of failed assertion states that are causally related to a common bug.

Although semi-formal bug hunting engines may reach states of the RTL design space that fully formal bug hunting cannot, semi-formal bug hunting engines are not without their own limitations. For one, scalability may still be difficult for more complex designs. As an example, a system on chip (SoC) design may include millions of gates and registers. Formal bug hunting engines may be expected to detect hard to find corner-case bugs in such a design, although doing so may require hundreds of central processing unit (CPU) cores and gigabytes of memory. As a result, thousands of semi-formal bug hunting searches may be run in parallel from different waypoints defined by thousands of helper properties, but current bug hunting engines have no structured way to handle searches of this scale.

Semi-formal bug hunting engines also must handle thousands of helper properties provided by users to help in reaching corner-case behaviors in an RTL design and to search for bugs in these corners using formal engines. Current bug-hunting engines, however, do not have any sort of structural support to learn from these helper properties and to make future bug hunting searches more effective.

Moreover, current bug hunting engines lack a feedback mechanism for orchestration (i.e., determining which engines to invoke, when to invoke the engines, and a time budget with which to invoke the engines, based on available resources). Feedback may be useful in customizing future bug hunting searches and adding helper properties to increase the likelihood of detecting more bugs.

Since current semi-formal bug hunting engines lack a structured framework to leverage information from previous bug hunting searches, there is no systemic approach for locating bug-prone zones in an RTL design. Therefore, it may not be possible for users or tools to sensitize such bug-prone zones and detect other related bugs from the bug-prone zones. For instance, an excess of helper goals may inadvertently obfuscate the causal relationship between helpers, bugs, and consequent failed assertions.

Examples of the present disclosure provide graph-based visualization of waypoints for detecting bugs in RTL designs. In one example, a graph may be defined that captures the relationship between helper properties and the failed assertions that may be reached through the helper properties. The graph may be created and maintained over multiple semi-formal bug hunting searches. The graph may subsequently be leveraged to search the design state space in a radius surrounding a failed assertion for related failed assertions (e.g., failed assertions resulting from a common bug). In further examples, the graph may help engineers to better visualize the search space, thereby enabling the engineers to selectively add and/or remove helper properties, drive subsequent bug hunting searches, and interact more effectively with bug hunting searches.

Technical advantages of the present disclosure include, but are not limited to, facilitating the detection of bugs in RTL designs that are difficult to detect using existing formal and semi-formal verification techniques (e.g., hard corner-case bugs). Examples of the present disclosure improve the functioning of a computer by accelerating the detection of hard corner-case bugs in RTL designs, thereby minimizing not just the time, but also the amount of computing resources, consumed during formal verification, which allows freed resources to be allocated to other tasks including other formal verification tasks.

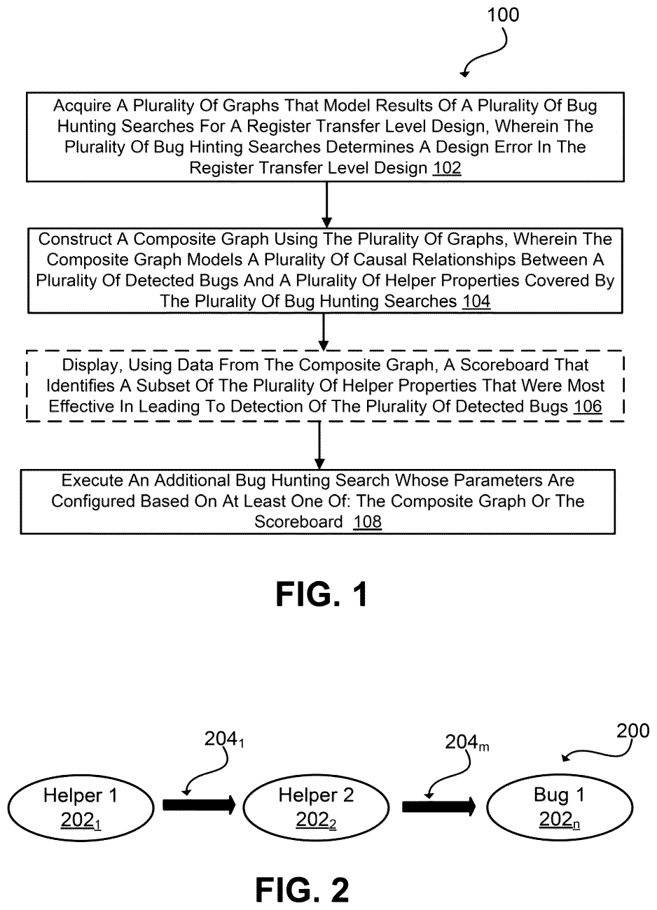

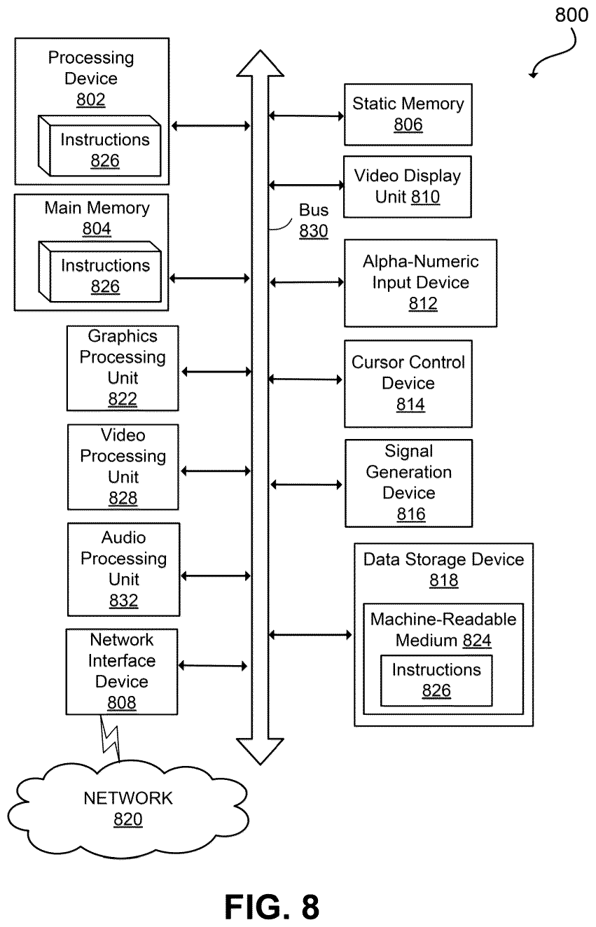

FIG. 1 illustrates a flow diagram of one example of a method 100 for visualizing waypoints for detecting design errors in integrated circuit designs. In one example, the method 100 may be performed by a processing device, such as the processing device 802 of the computer system 800 illustrated in FIG. 8. In other examples, however, the method 100 may be performed by another device. For example, the method 100 is described below as being performed by a processing system.

At 102, the processing system may acquire a plurality of graphs that model results of a plurality of bug hunting searches for a register transfer level design, wherein the plurality of bug hunting searches determines a design error in the register transfer level design.

In one example, the plurality of bug hunting searches may have been performed by a formal bug hunting engine, a semi-formal bug hunting engine, or a combination of formal and semi-formal bug hunting engines. Moreover, a plurality of different formal bug hunting engines and/or a plurality of different semi-formal bug hunting engines may have been used to perform the plurality of bug hunting searches. For instance, the plurality of bug hunting searches may be performed using bounded model checking and other types of bug hunting engines.

In one example, each graph of the plurality of graphs may be a directed graph that models potential causal relationships between bugs that were detected during a corresponding bug hunting search and the helper properties that enabled detection of the bugs, following the sequence in which the bugs were reached in the corresponding bug hunting search. In one example, each graph may include a plurality of vertices connected by a plurality of directed edges. Each vertex of the plurality of vertices represents either at least one helper property that was covered in a corresponding bug hunting search of the plurality of bug hunting searches or at least one bug that was detected in the corresponding bug hunting search. A directed edge between two vertices of the graph indicates that a helper property or bug represented by the origin vertex was covered or failed before the helper property or bug represented by the destination vertex in a corresponding bug hunting search.

FIG. 2, for instance, illustrates a fragment 200 of an example graph that may be constructed from a bug hunting search by a semi-formal bug hunting engine and acquired at 102 of FIG. 1. As illustrated, the fragment 200 includes a plurality of vertices 202₁-202ₙ (hereinafter collectively referred to as vertices 202 or individually referred to as a vertex 202) and a plurality of edges 204₁-204ₘ (hereinafter collectively referred to as edges 204 or individually referred to as an edge 204).

If a helper property (Helper 1) represented by vertex 202₁ has been matched by a bug hunting engine in a previous bug hunting search, then a new semi-formal bug hunting search can be initiated from the trace generated by Helper 1. During this new semi-formal bug hunting search, another helper property (Helper 2) represented by vertex 202₂ may be matched. Subsequently, another new semi-formal bug hunting search may be initiated from the trace generated by Helper 2, which may eventually lead to a bug (Bug 1) represented by vertex 202ₙ. The fragment 200 represents this sequence of matches. In one example, helper properties such as Helper 1 and Helper 2 may be user defined or automatically generated by a formal verification tool. Helper properties that are user defined may be referred to as user helpers, while helper properties that are defined by a formal verification tool may be referred to as tool helpers.

Bug hunting often involves thousands of semi-formal searches performed in the manner described above, running across multiple CPU cores. It is helpful to establish a complete picture of different helper properties that lead to the detection of different bugs in a bug hunting search.

At 104, the processing system may construct a composite graph using the plurality of graphs, wherein the composite graph models a plurality of causal relationships between a plurality of detected bugs and a plurality of helper properties covered by the plurality of bug hunting searches.

In one example, the composite graph may be constructed at 104 by merging fragments of the plurality of graphs to create a larger single graph which captures the relationships between all helper properties and all bugs detected during the plurality of bug hunting searches.

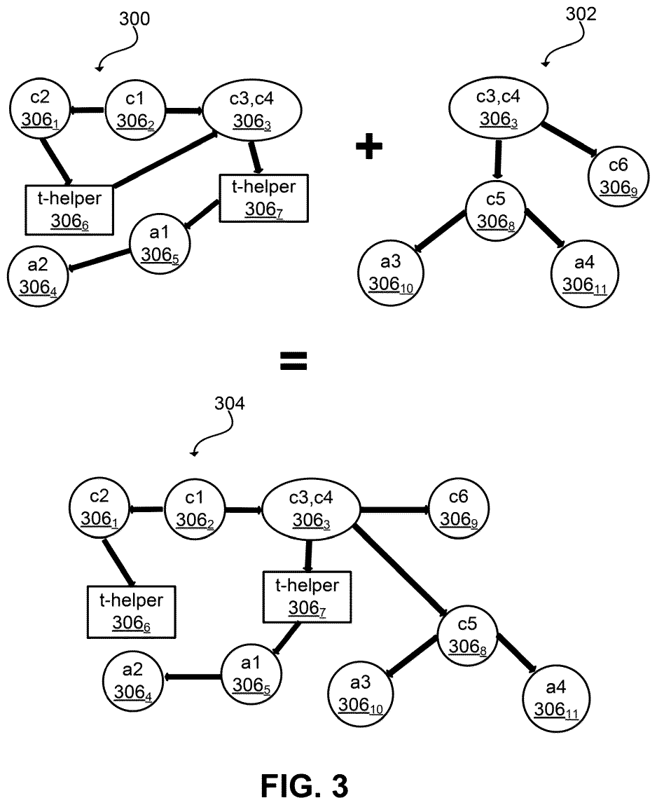

FIG. 3, for instance, illustrates a first example graph fragment 300 and a second example graph fragment 302 that may be merged to construct a composite graph 304. As illustrated, like the graph fragments 300 and 302, the composite graph 304 may include a plurality of vertices 306₁-306₁₁ (hereinafter collectively referred to as vertices 306 or individually referred to as a vertex 306) connected by a plurality of directed edges. In the example illustrated in FIG. 3, vertices 306₁-306₃ and 306₈-306₉ represent user helpers c1-c6 (i.e., helper properties defined by a user), vertices 306₆-306₇ represent tool helpers t-helper (i.e., helper properties that are defined by a formal verification tool), and vertices 306₄-306₅ and 306₁₀-306₁₁ represent detected bugs a1-a4. Some examples of detected bugs may include, for instance, RTL cycle-wise timing errors (e.g., off-by-one errors, control signals not arriving at proper times, and the like), testbench errors (e.g., compilation errors, misunderstood design under test functionality, and the like), compilation errors (wrong syntax, datatypes, missing conversions, and the like), and other types of bugs.

It should be noted that the graph fragments 300 and 302 are provided as non-limiting examples; a graph fragment according to the present disclosure may include any combination of user helpers and tool helpers, or may include solely user helpers or solely tool helpers. Moreover, though the example graph fragments 300 and 302 are illustrated as being relatively small, in practice, graph fragments are typically much larger, which makes manual merging of the graph fragments infeasible.

Merging the first graph fragment 300 and the second graph fragment 302 may involve identifying vertices that are common to both the first graph fragment 300 and the second graph fragment 302, such as vertex 306₃ representing user helpers c3 and c4. Vertex 306₃ therefore becomes a connection point via which the first graph fragment 300 and the second graph fragment 302 may be connected via the composite graph 304. Where two or more graph fragments share no common vertices, the graph fragments may still be merged to form a single graph containing all vertices and edges of both graph fragments.

At optional 106, the processing system may display, using data from the composite graph, a scoreboard that identifies a subset of the plurality of helper properties that were most effective in leading to detection of the plurality of detected bugs.

In one example, a scoreboard may be created from the composite graph to help easily identify not only which helper properties of the plurality of helper properties are most effective in leading to the detection of bugs, but also which helper properties are redundant or relatively ineffective in leading to the detection of bugs and which areas of the RTL design space are most prone to bugs (e.g., which areas of the RTL design space contain the greatest number of bugs relative to other areas of the RTL design, or contain a threshold percentage of the total number of detected bugs).

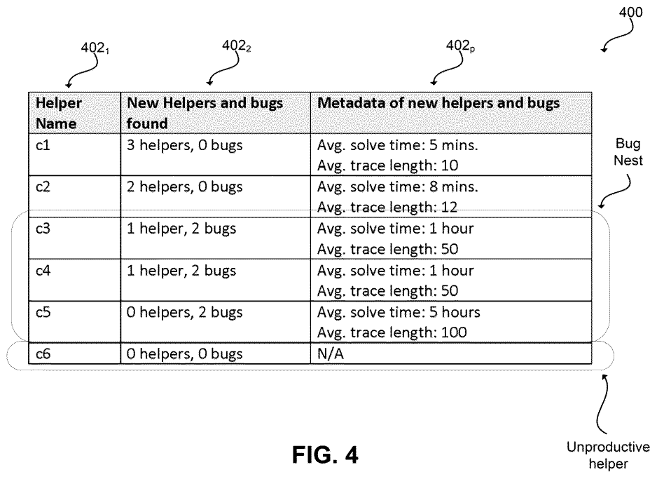

FIG. 4, for instance, illustrates an example scoreboard 400 that may be generated using the data in the example composite graph 300 of FIG. 3. As illustrated, the scoreboard 400 may contain an entry for each helper property of the plurality of helper properties. Each entry in the scoreboard 400 may include a plurality of fields 402₁-402ₚ (hereinafter collectively referred to as fields 402 or individually referred to as a field 402), including: a helper name field 402₁ which contains a name or identifier of the helper property, a new helpers and bugs found field 402₂ which contains counts of the numbers of new helper properties and new bugs to which the helper property led, and a metadata of new helpers and bugs field 402ₚ which contains metadata related to the helper property and/or to bugs found from the helper property. Metadata related to the helper property or to bugs found from the helper property might include the average time to solve the helper property or bug(s) (e.g., how much time has elapsed between the start of the bug hunting search and the solution of the helper property, typically measured in seconds, minutes, hours, and/or other units), an average trace length (e.g., number of clock cycles elapsed between an initial state and a time at which a failure associated with a bug occurred, typically measured in design cycles which may be defined by a user), and/or other metadata. Although the example scoreboard 400 includes three fields 402 for each entry, it will be appreciated that each entry may include more or fewer fields 402 than what is shown.

Several different heuristics may be applied to determine the effectiveness of a helper property. For instance, in one example, helper properties that lead to the detection of the largest numbers of bugs may be considered the most effective helper properties. In another example, helper properties that lead to the detection of the deepest bugs (e.g., located in the furthest or hardest to reach corners of the RTL design space) may be considered the most effective helper properties. In another example, helper properties that lead to the detection of the hardest bugs in terms of time to solve may be considered the most effective helper properties.

In the example of FIG. 4, if the heuristics applied consider the most effective helper properties to be the helper properties that lead to the detection of the deepest bugs and the hardest bugs in terms of time to solve, then the ranking of the helper properties from most effective to least effective would be c5, c3 and c4, c2, c1.

Furthermore, if one or more helper properties lead to the detection of multiple co-located bugs, then the area surrounding the one or more helper properties may be considered a bug-prone zone, or a bug nest. In the example of FIG. 4, the area surrounding helper properties c3, c4, and c5 may be considered a bug nest, because the helper properties c3, c4, and c5 lead to the detection of many bugs that either: (1) take a relatively long time to solve (e.g., the solve time exceeds a threshold time); or (2) reside deeper than a threshold cycle (e.g., deeper than at least fifty cycles).

The helper property c6 in FIG. 4 may be considered an unproductive helper property, because the helper property c6 does not lead to the detection of any other helper properties or bugs.

Referring back to FIG. 1, at 108, the processing system may execute an additional bug hunting search whose parameters are configured based on at least one of: the composite graph or the scoreboard.

As discussed above, a scoreboard may provide several insights into the plurality of bug hunting searches. If a system or a user can identify effective helper properties from previous bug hunting searches (e.g., with the assistance of a scoreboard such as the scoreboard 400 of FIG. 4), then additional bug hunting searches can be tuned accordingly to facilitate the detection of more bugs and more helper properties.

As an example, parameters of an additional bug hunting search may be tuned to explore more areas of the RTL design space that are proximal to (e.g., within some threshold distance of) helper properties of the plurality of helper properties that were determined to be most effective. Within this context, distance refers to a number of design cycles. For instance, a helper property may be solved during cycle 50. In this case, an additional bug hunting search may be performed in the range of cycles 40 through 60.

As another example, parameters of an additional bug hunting search may be tuned to add more helper properties to sensitize (e.g., perform a further search of) a bug-prone zone of the RTL design space (e.g., a zone containing at least a threshold number of bugs). By sensitizing the bug-prone zone or bug nest, many more bugs related to the plurality of detected bugs may be detected. The bug nest may be sensitized by providing a recommendation or indication to perform an additional semi-formal search around certain helper properties and/or to display a graphic on a user interface to request additional helper properties around the bug nest.

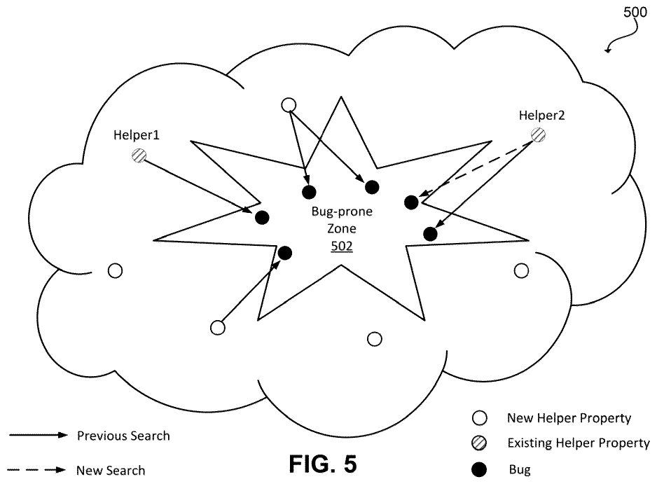

FIG. 5, for instance, illustrates a graphic showing how insights derived from a scoreboard such as the scoreboard 400 of FIG. 4 may be used to tune the parameters of new bug hunting searches to detect additional bugs in a bug-prone zone of a register transfer level design space 500 (illustrated in FIG. 5 as a cloud). In the example of FIG. 5, a scoreboard may have indicated that existing helper properties identified as Helper 1 and Helper 2 were effective helper properties that led, in previous bug hunting searches, to the detection of deep bugs in the RTL design space. This insight may motivate the addition, in a new bug hunting search, of a plurality of new helper properties in the area surrounding these deep bugs (e.g., surrounding bug-prone zone 502 which encompasses the deep bugs). The new helper properties, in turn, may lead to new semi-formal searches which may help in detecting additional bugs in the area of the deep bugs.

Experimental results have shown that examples of the present disclosure may lead to a significant increase in the number of bugs detected in an RTL design. For instance, several semi-formal bug hunting searches were performed over multiple days with 14,000 properties at setup, 10,000 helper properties, and 1,500 assertions. This bug hunting search reached 5,000 helper properties and detected two bugs.

By contrast, when a composite graph was created using graph representations of these bug hunting searches, the composite graph led to the identification of the subset of helper properties that led to the detection of the two bugs. Additional semi-formal bug hunting searches were subsequently performed in the areas proximal to the subset of helper properties, resulting in 8,000 helper properties being reached and twenty-four bugs.

Thus, according to one example of the present disclosure, a non-transitory computer readable medium includes stored instructions, which when executed by a processor, cause the processor to acquire a plurality of graphs that model results of a plurality of bug hunting searches for a register transfer level design, wherein the plurality of bug hunting searches determines a design error in the register transfer level design, construct a composite graph using the plurality of graphs, wherein the composite graph models a plurality of causal relationships between a plurality of detected bugs and a plurality of helper properties covered by the plurality of bug hunting searches, and execute an additional bug hunting search whose parameters are configured based on the composite graph.

In another example, a method includes acquiring a plurality of graphs that model results of a plurality of bug hunting searches for a register transfer level design, wherein the plurality of bug hunting searches determines a design error in the register transfer level design, constructing a composite graph using the plurality of graphs, wherein the composite graph models a plurality of causal relationships between a plurality of detected bugs and a plurality of helper properties covered by the plurality of bug hunting searches, and executing a new bug hunting search whose parameters are configured based on the composite graph.

In another example, system includes a memory storing instructions and a processor coupled with the memory and to execute the instructions. When the instructions are executed, the instructions cause the processor to acquire a plurality of graphs that model results of a plurality of bug hunting searches for a register transfer level design, wherein the plurality of bug hunting searches determines a design error in the register transfer level design, construct a composite graph using the plurality of graphs, wherein the composite graph models a plurality of causal relationships between a plurality of detected bugs and a plurality of helper properties covered by the plurality of bug hunting searches, display, using data from the composite graph, a scoreboard that identifies a subset of the plurality of helper properties that were most effective in leading to detection of the plurality of detected bugs, and execute a new bug hunting search whose parameters are configured based on the scoreboard.

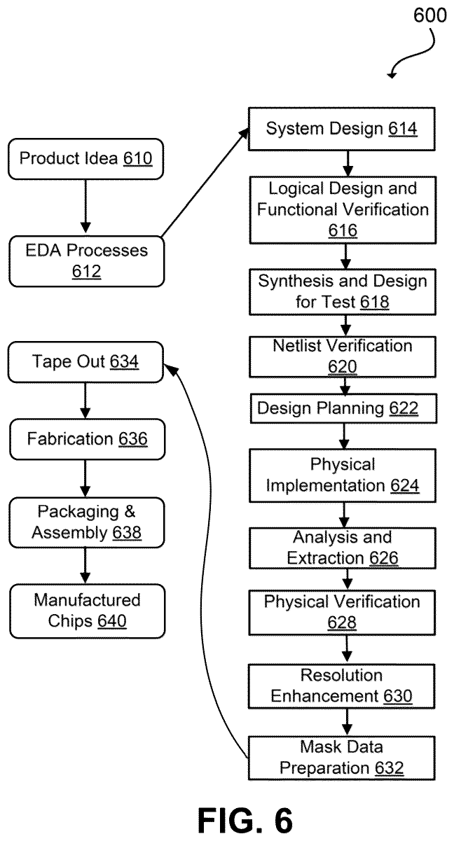

FIG. 6 illustrates an example set of processes 600 used during the design, verification, and fabrication of an article of manufacture such as an integrated circuit to transform and verify design data and instructions that represent the integrated circuit. Each of these processes can be structured and enabled as multiple modules or operations. The term “EDA” signifies the term “Electronic Design Automation.” These processes start with the creation of a product idea 610 with information supplied by a designer, information which is transformed to create an article of manufacture that uses a set of EDA processes 612. When the design is finalized, the design is taped-out 634, which is when artwork (e.g., geometric patterns) for the integrated circuit is sent to a fabrication facility to manufacture the mask set, which is then used to manufacture the integrated circuit. After tape-out, a semiconductor die is fabricated 636 and packaging and assembly processes 638 are performed to produce the finished integrated circuit 640.

Specifications for a circuit or electronic structure may range from low-level transistor material layouts to high-level description languages. A high-level of representation may be used to design circuits and systems, using a hardware description language (“HDL”) such as VHDL, Verilog, SystemVerilog, SystemC, MyHDL or OpenVera. The HDL description can be transformed to a logic-level register transfer level (“RTL”) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 6. The processes described by be enabled by EDA products (or EDA systems).

During system design 614, a functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 616, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as “emulators” or “prototyping systems” are used to speed up the functional verification.

During synthesis and design for test 618, HDL code is transformed to a netlist. In some embodiments, a netlist may be a graph structure where edges of the graph structure represent components of a circuit and where the vertices of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 620, the netlist is checked for compliance with timing constraints and for correspondence with the HDL code. During design planning 622, an overall floor plan for the integrated circuit is constructed and analyzed for timing and top-level routing.

During layout or physical implementation 624, physical placement (positioning of circuit components such as transistors or capacitors) and routing (connection of the circuit components by multiple conductors) occurs, and the selection of cells from a library to enable specific logic functions can be performed. As used herein, the term “cell” may specify a set of transistors, other components, and interconnections that provides a Boolean logic function (e.g., AND, OR, NOT, XOR) or a storage function (such as a flipflop or latch). As used herein, a circuit “block” may refer to two or more cells. Both a cell and a circuit block can be referred to as a module or component and are enabled as both physical structures and in simulations. Parameters are specified for selected cells (based on “standard cells”) such as size and made accessible in a database for use by EDA products.

During analysis and extraction 626, the circuit function is verified at the layout level, which permits refinement of the layout design. During physical verification 628, the layout design is checked to ensure that manufacturing constraints are correct, such as DRC constraints, electrical constraints, lithographic constraints, and that circuitry function matches the HDL design specification. During resolution enhancement 630, the geometry of the layout is transformed to improve how the circuit design is manufactured.

During tape-out, data is created to be used (after lithographic enhancements are applied if appropriate) for production of lithography masks. During mask data preparation 632, the “tape-out” data is used to produce lithography masks that are used to produce finished integrated circuits.

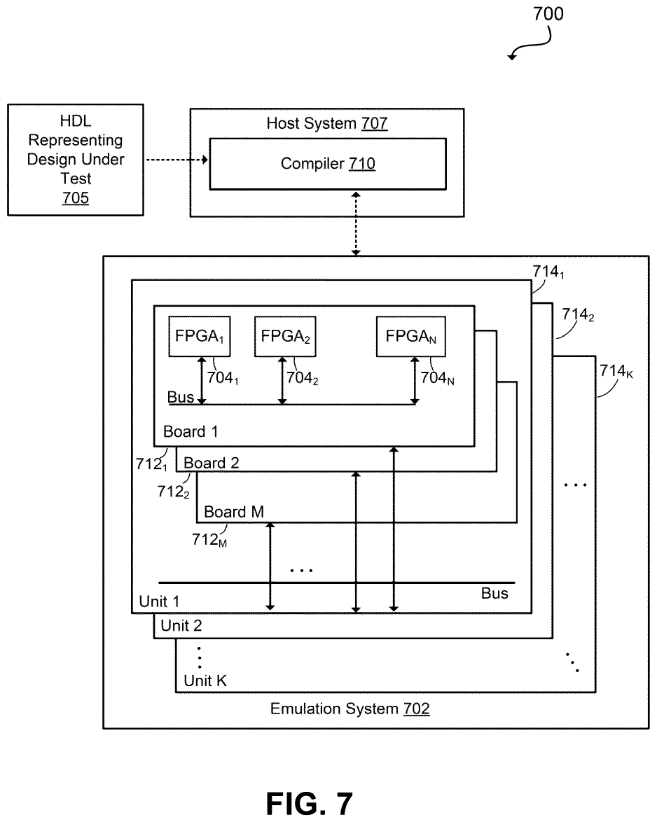

A storage subsystem of a computer system (such as computer system 800 of FIG. 8, or host system 707 of FIG. 7) may be used to store the programs and data structures that are used by some or all of the EDA products described herein, and products used for development of cells for the library and for physical and logical design that use the library.

FIG. 7 depicts a diagram of an example emulation environment 700. An emulation environment 700 may be configured to verify the functionality of the circuit design. The emulation environment 700 may include a host system 707 (e.g., a computer that is part of an EDA system) and an emulation system 702 (e.g., a set of programmable devices such as Field Programmable Gate Arrays (FPGAs) or processors). The host system generates data and information by using a compiler 710 to structure the emulation system to emulate a circuit design. A circuit design to be emulated is also referred to as a Design Under Test (“DUT”) where data and information from the emulation are used to verify the functionality of the DUT.

The host system 707 may include one or more processors. In the embodiment where the host system includes multiple processors, the functions described herein as being performed by the host system can be distributed among the multiple processors. The host system 707 may include a compiler 710 to transform specifications written in a description language that represents a DUT and to produce data (e.g., binary data) and information that is used to structure the emulation system 702 to emulate the DUT. The compiler 710 can transform, change, restructure, add new functions to, and/or control the timing of the DUT.

The host system 707 and emulation system 702 exchange data and information using signals carried by an emulation connection. The connection can be, but is not limited to, one or more electrical cables such as cables with pin structures compatible with the Recommended Standard 232 (RS232) or universal serial bus (USB) protocols. The connection can be a wired communication medium or network such as a local area network or a wide area network such as the Internet. The connection can be a wireless communication medium or a network with one or more points of access using a wireless protocol such as BLUETOOTH or IEEE 802.11. The host system 707 and emulation system 702 can exchange data and information through a third device such as a network server.

The emulation system 702 includes multiple FPGAs (or other modules) such as FPGAs 704₁ and 704₂ as well as additional FPGAs to 704_{N}. Each FPGA can include one or more FPGA interfaces through which the FPGA is connected to other FPGAs (and potentially other emulation components) for the FPGAs to exchange signals. An FPGA interface can be referred to as an input/output pin or an FPGA pad. While an emulator may include FPGAs, embodiments of emulators can include other types of logic blocks instead of, or along with, the FPGAs for emulating DUTs. For example, the emulation system 702 can include custom FPGAs, specialized ASICs for emulation or prototyping, memories, and input/output devices.

A programmable device can include an array of programmable logic blocks and a hierarchy of interconnections that can enable the programmable logic blocks to be interconnected according to the descriptions in the HDL code. Each of the programmable logic blocks can enable complex combinational functions or enable logic gates such as AND, and XOR logic blocks. In some embodiments, the logic blocks also can include memory elements/devices, which can be simple latches, flip-flops, or other blocks of memory. Depending on the length of the interconnections between different logic blocks, signals can arrive at input terminals of the logic blocks at different times and thus may be temporarily stored in the memory elements/devices.

FPGAs 704₁-704_{N} may be placed onto one or more boards 712₁ and 712₂ as well as additional boards through 712_{M}. Multiple boards can be placed into an emulation unit 714₁. The boards within an emulation unit can be connected using the backplane of the emulation unit or any other types of connections. In addition, multiple emulation units (e.g., 714₁ and 714₂ through 714_{K}) can be connected to each other by cables or any other means to form a multi-emulation unit system.

For a DUT that is to be emulated, the host system 707 transmits one or more bit files to the emulation system 702. The bit files may specify a description of the DUT and may further specify partitions of the DUT created by the host system 707 with trace and injection logic, mappings of the partitions to the FPGAs of the emulator, and design constraints. Using the bit files, the emulator structures the FPGAs to perform the functions of the DUT. In some embodiments, one or more FPGAs of the emulators may have the trace and injection logic built into the silicon of the FPGA. In such an embodiment, the FPGAs may not be structured by the host system to emulate trace and injection logic.

The host system 707 receives a description of a DUT that is to be emulated. In some embodiments, the DUT description is in a description language (e.g., a register transfer language (RTL)). In some embodiments, the DUT description is in netlist level files or a mix of netlist level files and HDL files. If part of the DUT description or the entire DUT description is in an HDL, then the host system can synthesize the DUT description to create a gate level netlist using the DUT description. A host system can use the netlist of the DUT to partition the DUT into multiple partitions where one or more of the partitions include trace and injection logic. The trace and injection logic traces interface signals that are exchanged via the interfaces of an FPGA. Additionally, the trace and injection logic can inject traced interface signals into the logic of the FPGA. The host system maps each partition to an FPGA of the emulator. In some embodiments, the trace and injection logic is included in select partitions for a group of FPGAs. The trace and injection logic can be built into one or more of the FPGAs of an emulator. The host system can synthesize multiplexers to be mapped into the FPGAs. The multiplexers can be used by the trace and injection logic to inject interface signals into the DUT logic.

The host system creates bit files describing each partition of the DUT and the mapping of the partitions to the FPGAs. For partitions in which trace and injection logic are included, the bit files also describe the logic that is included. The bit files can include place and route information and design constraints. The host system stores the bit files and information describing which FPGAs are to emulate each component of the DUT (e.g., to which FPGAs each component is mapped).

Upon request, the host system transmits the bit files to the emulator. The host system signals the emulator to start the emulation of the DUT. During emulation of the DUT or at the end of the emulation, the host system receives emulation results from the emulator through the emulation connection. Emulation results are data and information generated by the emulator during the emulation of the DUT which include interface signals and states of interface signals that have been traced by the trace and injection logic of each FPGA. The host system can store the emulation results and/or transmits the emulation results to another processing system.

After emulation of the DUT, a circuit designer can request to debug a component of the DUT. If such a request is made, the circuit designer can specify a time period of the emulation to debug. The host system identifies which FPGAs are emulating the component using the stored information. The host system retrieves stored interface signals associated with the time period and traced by the trace and injection logic of each identified FPGA. The host system signals the emulator to re-emulate the identified FPGAs. The host system transmits the retrieved interface signals to the emulator to re-emulate the component for the specified time period. The trace and injection logic of each identified FPGA injects its respective interface signals received from the host system into the logic of the DUT mapped to the FPGA. In case of multiple re-emulations of an FPGA, merging the results produces a full debug view.

The host system receives, from the emulation system, signals traced by logic of the identified FPGAs during the re-emulation of the component. The host system stores the signals received from the emulator. The signals traced during the re-emulation can have a higher sampling rate than the sampling rate during the initial emulation. For example, in the initial emulation a traced signal can include a saved state of the component every X milliseconds. However, in the re-emulation the traced signal can include a saved state every Y milliseconds where Y is less than X. If the circuit designer requests to view a waveform of a signal traced during the re-emulation, the host system can retrieve the stored signal and display a plot of the signal. For example, the host system can generate a waveform of the signal. Afterwards, the circuit designer can request to re-emulate the same component for a different time period or to re-emulate another component.

A host system 707 and/or the compiler 710 may include sub-systems such as, but not limited to, a design synthesizer sub-system, a mapping sub-system, a run time sub-system, a results sub-system, a debug sub-system, a waveform sub-system, and a storage sub-system. The sub-systems can be structured and enabled as individual or multiple modules or two or more may be structured as a module. Together these sub-systems structure the emulator and monitor the emulation results.

The design synthesizer sub-system transforms the HDL that is representing a DUT 805 into gate level logic. For a DUT that is to be emulated, the design synthesizer sub-system receives a description of the DUT. If the description of the DUT is fully or partially in HDL (e.g., RTL or other level of representation), the design synthesizer sub-system synthesizes the HDL of the DUT to create a gate-level netlist with a description of the DUT in terms of gate level logic.

The mapping sub-system partitions DUTs and maps the partitions into emulator FPGAs. The mapping sub-system partitions a DUT at the gate level into a number of partitions using the netlist of the DUT. For each partition, the mapping sub-system retrieves a gate level description of the trace and injection logic and adds the logic to the partition. As described above, the trace and injection logic included in a partition is used to trace signals exchanged via the interfaces of an FPGA to which the partition is mapped (trace interface signals). The trace and injection logic can be added to the DUT prior to the partitioning. For example, the trace and injection logic can be added by the design synthesizer sub-system prior to or after the synthesizing the HDL of the DUT.

In addition to including the trace and injection logic, the mapping sub-system can include additional tracing logic in a partition to trace the states of certain DUT components that are not traced by the trace and injection. The mapping sub-system can include the additional tracing logic in the DUT prior to the partitioning or in partitions after the partitioning. The design synthesizer sub-system can include the additional tracing logic in an HDL description of the DUT prior to synthesizing the HDL description.

The mapping sub-system maps each partition of the DUT to an FPGA of the emulator. For partitioning and mapping, the mapping sub-system uses design rules, design constraints (e.g., timing or logic constraints), and information about the emulator. For components of the DUT, the mapping sub-system stores information in the storage sub-system describing which FPGAs are to emulate each component.

Using the partitioning and the mapping, the mapping sub-system generates one or more bit files that describe the created partitions and the mapping of logic to each FPGA of the emulator. The bit files can include additional information such as constraints of the DUT and routing information of connections between FPGAs and connections within each FPGA. The mapping sub-system can generate a bit file for each partition of the DUT and can store the bit file in the storage sub-system. Upon request from a circuit designer, the mapping sub-system transmits the bit files to the emulator, and the emulator can use the bit files to structure the FPGAs to emulate the DUT.

If the emulator includes specialized ASICs that include the trace and injection logic, the mapping sub-system can generate a specific structure that connects the specialized ASICs to the DUT. In some embodiments, the mapping sub-system can save the information of the traced/injected signal and where the information is stored on the specialized ASIC.

The run time sub-system controls emulations performed by the emulator. The run time sub-system can cause the emulator to start or stop executing an emulation. Additionally, the run time sub-system can provide input signals and data to the emulator. The input signals can be provided directly to the emulator through the connection or indirectly through other input signal devices. For example, the host system can control an input signal device to provide the input signals to the emulator. The input signal device can be, for example, a test board (directly or through cables), signal generator, another emulator, or another host system.

The results sub-system processes emulation results generated by the emulator. During emulation and/or after completing the emulation, the results sub-system receives emulation results from the emulator generated during the emulation. The emulation results include signals traced during the emulation. Specifically, the emulation results include interface signals traced by the trace and injection logic emulated by each FPGA and can include signals traced by additional logic included in the DUT. Each traced signal can span multiple cycles of the emulation. A traced signal includes multiple states and each state is associated with a time of the emulation. The sub-system stores the traced signals in the storage sub-system. For each stored signal, the results sub-system can store information indicating which FPGA generated the traced signal.

The debug sub-system allows circuit designers to debug DUT components. After the emulator has emulated a DUT and the results sub-system has received the interface signals traced by the trace and injection logic during the emulation, a circuit designer can request to debug a component of the DUT by re-emulating the component for a specific time period. In a request to debug a component, the circuit designer identifies the component and indicates a time period of the emulation to debug. The circuit designer's request can include a sampling rate that indicates how often states of debugged components should be saved by logic that traces signals.

The debug sub-system identifies one or more FPGAs of the emulator that are emulating the component using the information stored by the mapping sub-system in the storage sub-system. For each identified FPGA, the debug sub-system retrieves, from the storage sub-system, interface signals traced by the trace and injection logic of the FPGA during the time period indicated by the circuit designer. For example, the debug sub-system retrieves states traced by the trace and injection logic that are associated with the time period.

The debug sub-system transmits the retrieved interface signals to the emulator. The debug sub-system instructs the debug sub-system to use the identified FPGAs and for the trace and injection logic of each identified FPGA to inject its respective traced signals into logic of the FPGA to re-emulate the component for the requested time period. The debug sub-system can further transmit the sampling rate provided by the circuit designer to the emulator so that the tracing logic traces states at the proper intervals.

To debug the component, the emulator can use the FPGAs to which the component has been mapped. Additionally, the re-emulation of the component can be performed at any point specified by the circuit designer.

For an identified FPGA, the debug sub-system can transmit instructions to the emulator to load multiple emulator FPGAs with the same configuration of the identified FPGA. The debug sub-system additionally signals the emulator to use the multiple FPGAs in parallel. Each FPGA from the multiple FPGAs is used with a different time window of the interface signals to generate a larger time window in a shorter amount of time. For example, the identified FPGA can require an hour or more to use a certain amount of cycles. However, if multiple FPGAs have the same data and structure of the identified FPGA and each of these FPGAs runs a subset of the cycles, the emulator can require a few minutes for the FPGAs to collectively use all the cycles.

A circuit designer can identify a hierarchy or a list of DUT signals to re-emulate. To enable this, the debug sub-system determines the FPGA needed to emulate the hierarchy or list of signals, retrieves the necessary interface signals, and transmits the retrieved interface signals to the emulator for re-emulation. Thus, a circuit designer can identify any element (e.g., component, device, or signal) of the DUT to debug/re-emulate.

The waveform sub-system generates waveforms using the traced signals. If a circuit designer requests to view a waveform of a signal traced during an emulation run, the host system retrieves the signal from the storage sub-system. The waveform sub-system displays a plot of the signal. For one or more signals, when the signals are received from the emulator, the waveform sub-system can automatically generate the plots of the signals.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A non-transitory computer readable medium comprising stored instructions, which when executed by a processor, cause the processor to:
acquire a plurality of graphs that model results of a plurality of bug hunting searches for a register transfer level design, wherein the plurality of bug hunting searches determines a design error in the register transfer level design;
construct a composite graph using the plurality of graphs, wherein the composite graph models a plurality of causal relationships between a plurality of detected bugs and a plurality of helper properties covered by the plurality of bug hunting searches; and
execute an additional bug hunting search whose parameters are configured based on the composite graph.

2. The non-transitory computer readable medium of claim 1, wherein the plurality of bug hunting searches was performed by at least one of: a formal bug hunting method or a semi-formal bug hunting method.

3. The non-transitory computer readable medium of claim 1, wherein each graph of the plurality of graphs comprises:
a plurality of vertices, wherein each vertex of the plurality of vertices represents one of: a helper property of the plurality of helper properties that was covered by a corresponding bug hunting search of the plurality of bug hunting searches or a detected bug of the plurality of detected bugs that was detected in the corresponding bug hunting search of the plurality of bug hunting searches; and
a plurality of directed edges connecting the plurality of vertices, wherein each directed edge of the plurality of directed edges indicates that a helper property or a detected bug represented by an origin vertex of the plurality of vertices was covered or failed before a helper property or a bug represented by a destination vertex of the plurality of vertices.

4. The non-transitory computer readable medium of claim 3, wherein the constructing the composite graph comprises merging fragments of the plurality of graphs to create a single graph that models the plurality of causal relationships between the plurality of helper properties and the plurality of detected bugs.

5. The non-transitory computer readable medium of claim 4, wherein the merging comprises identifying vertices of the plurality of vertices that are common to at least two graphs of the plurality of graphs, wherein the vertices of the plurality of vertices that are common to the at least two graphs of the plurality of graphs are used to connect the at least two graphs of the plurality of graphs.

6. The non-transitory computer readable medium of claim 1, wherein the instructions further cause the processor to:
display, using data from the composite graph, a scoreboard that identifies a subset of the plurality of helper properties that were most effective in leading to detection of the plurality of detected bugs.

7. The non-transitory computer readable medium of claim 6, wherein the scoreboard contains an entry for each helper property of the plurality of helper properties, wherein the entry includes a plurality of fields, and wherein the plurality of fields includes a field containing at least one of: an identifier of the each helper property, a count of a number of new helper properties of the plurality of helper properties to which the each helper property led, a count of a number of bugs of the plurality of detected bugs to which the each helper property led, or metadata related to the each helper property or to the number of bugs of the plurality of detected bugs.

8. The non-transitory computer readable medium of claim 7, wherein the metadata includes at least one of: an average time to solve the each helper property, an average trace length of the each helper property, an average time to solve the number of bugs of the plurality of detected bugs, or an average trace length of the number of bugs of the plurality of detected bugs.

9. The non-transitory computer readable medium of claim 1, wherein the instructions further cause the processor to tune the parameters to explore additional areas of the register transfer level design that are within a threshold distance of a helper property of the plurality of helper properties that was determined to lead to a detection of a desired numbers of bugs of the plurality of detected bugs.

10. The non-transitory computer readable medium of claim 1, wherein the instructions further cause the processor to tune the parameters to explore additional areas of the register transfer level design that are within a threshold distance of a helper property of the plurality of helper properties that was determined to lead to a detection of a bug with a desired depth of the plurality of detected bugs.

11. The non-transitory computer readable medium of claim 1, wherein the instructions further cause the processor to tune the parameters to explore additional areas of the register transfer level design that are within a threshold distance of a helper property of the plurality of helper properties that was determined to lead to the detection of a hardest bug, in terms of time to solve, of the plurality of detected bugs.

12. The non-transitory computer readable medium of claim 1, wherein the instructions further cause the processor to tune the parameters to add new helper properties to perform a further bug hunting search of a zone of the register transfer level design that is determined, based on the composite graph, to be contain at least a threshold number of bugs.

13. A method comprising:
acquiring a plurality of graphs that model results of a plurality of bug hunting searches for a register transfer level design wherein the plurality of bug hunting searches determines a design error in the register transfer level design,;
constructing a composite graph using the plurality of graphs, wherein the composite graph models a plurality of causal relationships between a plurality of detected bugs and a plurality of helper properties covered by the plurality of bug hunting searches; and
executing an additional bug hunting search whose parameters are configured based on the composite graph.

14. A system comprising:
a memory storing instructions; and
a processor, coupled with the memory and to execute the instructions, the instructions when executed cause the processor to:
acquire a plurality of graphs that model results of a plurality of bug hunting searches for a register transfer level design wherein the plurality of bug hunting searches determines a design error in the register transfer level design,;
construct a composite graph using the plurality of graphs, wherein the composite graph models a plurality of causal relationships between a plurality of detected bugs and a plurality of helper properties covered by the plurality of bug hunting searches;
display, using data from the composite graph, a scoreboard that identifies a subset of the plurality of helper properties that were most effective in leading to detection of the plurality of detected bugs; and
execute an additional bug hunting search whose parameters are configured based on the scoreboard.

15. The system of claim 14, wherein the scoreboard contains an entry for each helper property of the plurality of helper properties, wherein the entry includes a plurality of fields, and wherein the plurality of fields includes a field containing at least one of: an identifier of the each helper property, a count of a number of new helper properties of the plurality of helper properties to which the each helper property led, a count of a number of bugs of the plurality of detected bugs to which the each helper property led, or metadata related to the each helper property or to the number of bugs of the plurality of detected bugs.

16. The system of claim 15, wherein the metadata includes at least one of: an average time to solve the each helper property, an average trace length of the each helper property, an average time to solve the number of bugs of the plurality of detected bugs, or an average trace length of the number of bugs of the plurality of detected bugs.

17. The system of claim 14, wherein the instructions further cause the processor to tune the parameters to explore additional areas of the register transfer level design that are within a threshold distance of a helper property of the plurality of helper properties that was determined to lead to a detection of a desired numbers of bugs of the plurality of detected bugs.

18. The system of claim 14, wherein the instructions further cause the processor to tune the parameters to explore additional areas of the register transfer level design that are within a threshold distance of a helper property of the plurality of helper properties that was determined to lead to a detection of a bug with a desired depth of the plurality of detected bugs.

19. The system of claim 14, wherein the instructions further cause the processor to tune the parameters to explore additional areas of the register transfer level design that are within a threshold distance of a helper property of the plurality of helper properties that was determined to lead to the detection of a hardest bug, in terms of time to solve, of the plurality of detected bugs.

20. The system of claim 14, wherein the instructions further cause the processor to tune the parameters to add new helper properties to perform a further bug hunting search of a zone of the register transfer level design that is determined, based on the composite graph, to be contain at least a threshold number of bugs.
